(19) United States
(12) Patent Application Publication
(10) Pub. No.: US 2009/0017229 A1
(43) Pub. Date: Jan. 15, 2009

(54) Processing System Platen having a Variable Thermal Conductivity Profile

(75) Inventors: Vikram Singh, North Andover, MA (US); Richard S. Muka, Topsfield, MA (US); Timothy J. Miller, Ipswich, MA (US); Changhoon Choi, Somerville, MA (US)

Correspondence Address: RAUSCHENBACH PATENT LAW GROUP, LLC, P.O. BOX 387, BEDFORD, MA, 01730, US

(73) Assignee: VARIAN SEMICONDUCTOR EQUIPMENT ASSOCIATES, INC., Gloucester, MA (US)

(21) Appl. No.: 12/143,489

(22) Filed: Jun. 20, 2008

Related U.S. Application Data
(60) Provisional application No. 60/948,725, filed on Jul. 10, 2007.

(51) Int. Cl. H05H 1/22; C23C 16/00

(52) U.S. Cl. 427/573; 118/723 E

(57) ABSTRACT

A platen for a processing system includes a first and a second thermal region that are separated by at least one boundary. A first fluid conduit is positioned in the first thermal region. A second fluid conduit is positioned in the second thermal region. A fluid reservoir having a first output is coupled to the first fluid conduit and a second output that is coupled to the second fluid conduit. The fluid reservoir provides fluid to the first fluid conduit with first fluid conditions that provides a first thermal conductivity to the first thermal region and provides fluid to the second fluid conduit with second fluid conditions that provides a second thermal conductivity to the second thermal region so that a predetermined thermal conductivity profile is achieved in the platen.

### RELATED APPLICATION SECTION

This application claims priority to U.S. Provisional Patent Application Ser. No. 60/948,725, filed Jul. 10, 2007, and entitled “System for Maintaining Workpiece Condition Uniform.” The entire application of U.S. Provisional Patent Application Ser. No. 60/948,725 is incorporated herein by reference.

The section headings used herein are for organizational purposes only and should not to be construed as limiting the subject matter described in the present application.

### BACKGROUND

Semiconductors have been widely used in many products including semiconductor devices. There has been a considerable effort to improve device manufacturing processes to improve the performance of the devices. In general, a large number of semiconductor devices may be formed on a single semiconductor substrate. Depending on the complexity of the semiconductor device, the substrate may undergo numerous processes.

A plasma based process may be one of such semiconductor device manufacturing processes. In particular, the plasma based process may be used for cleaning, etching, and milling the substrate, or for depositing material on the substrate. More recently, the plasma based process has been used as a doping or implanting process. As known in the art, the doping or implanting process is a process of introducing impurities to the substrate to alter electrical, optical, and/or mechanical properties of the substrate. The plasma doping, sometimes referred to as PLAD or plasma immersion ion implantation (PIII), process has been developed to meet the doping requirements of state-of-the-art electronic and optical devices.

The PLAD process may differ from conventional beam-line ion implantation process. In the beam-line ion implantation process, ions of desirable species may be generated in an ion source of the beam-line ion implantation system. The generated ions are then extracted by extraction electrodes and accelerated, in a prescribed energy, toward a front surface of the substrate. In the process of accelerating the ions toward the substrate, the ions may be filtered according to their mass-to-charge ratio, and only the desirable ions may be implanted to the substrate.

In the PLAD process, the substrate may be immersed in the plasma containing dopant ions. The substrate may be bias with a series of voltage pulses to attract ions from the plasma, and the attracted ions may be implanted to the substrate. The term “substrate” is defined herein as a metallic, semiconducting, insulating workpiece being implanted.

As known in the art, a system for performing the PLAD process may include a chamber, a dielectric window, and a radio frequency (RF) coil placed near the dielectric window. A substrate supported by a platen may be disposed in the chamber. In several systems, the dielectric window may be a cylindrical dielectric window, and the coil may be a helical coil surrounding the cylindrical dielectric window. In some other systems, the dielectric window may be a horizontally extending dielectric window, and the coil may be planar coil disposed above the horizontally extending dielectric window.

In operation, the chamber of the PLAD system may be evacuated to a low pressure suitable for striking and sustaining plasma. At least one process gas including impurities may be introduced into the chamber. Thereafter, a radio frequency current may be applied to the coil to convert the processing gas to plasma. In the plasma, electrons, ions of the process gas, neutrals, and residuals may be contained. A bias voltage may be applied to the substrate, and ions contained in the plasma may be accelerated and implanted in the substrate.

As known in the art, the PLAD process may be a high temperature process. The plasma may generate a great amount of heat. In addition, heat may be generated and applied to the substrate as the ions are implanted in the substrate. As known in the art, excessive heat applied to the substrate may result in devices with poor performance and/or may reduce the device yield.

To compensate for the harmful effect associated with the excessive heat, various methods and apparatus have been proposed. One proposal provides a platen containing spaces for providing cooling gas near the back surface of the substrate as the front surface of the substrate is processed. By providing the cooling gas near the back surface, the temperature of the substrate may be lowered, and the harmful effect of the excessive heat may be lessened.

However, excessive heat is only one of several adverse effects related to the heat generated or applied to the substrate during the substrate processing. Although the platen described above may compensate one of such effects, the platen may be incapable of addressing other adverse heat related effects. As such, better method and apparatus are needed.

### BRIEF DESCRIPTION OF THE DRAWINGS

The disclosure, in accordance with preferred and exemplary embodiments, together with further advantages thereof, is more particularly described in the following detailed description, taken in conjunction with the accompanying drawings. The drawings are not necessarily to scale, emphasis instead generally being placed upon illustrating principles of the disclosure.

FIG. 1A illustrates a temperature profile of a substrate during plasma processing, such as plasma doping, under a first processing environment.

FIG. 1B illustrates a temperature profile of a substrate during plasma processing, such as plasma doping, under a second processing environment.

FIG. 1C illustrates a temperature profile of a substrate during plasma processing, such as plasma doping, under a third processing conditions.

FIG. 2A is a simplified plan view of a platen according to one embodiment of the present disclosure that maintains a uniform substrate temperature profile while plasma processing.

FIG. 2B is a detailed plan view of the platen shown in FIG. 2A that maintains a uniform substrate temperature profile while plasma processing according to one embodiment of the present disclosure.

FIG. 2C illustrates a side-view of the platen and the substrate that are described in connection with FIGS. 2A-2B.

FIG. 3 is a plan view of another embodiment of a platen according to the present disclosure with a central region and a plurality of adjacent regions.

FIG. 4 is a plan view of yet another embodiment of a platen according to the present disclosure with a central region and a plurality of adjacent regions in first and second sub-regions.

FIG. 5 is a plan view of yet another embodiment of a platen according to the present disclosure that includes a plurality of rectangular regions that are positioned in a matrix.

FIG. 6 illustrates one embodiment of a fluid supply that provides fluids to a platen according to the present disclosure.

FIG. 7 illustrates another embodiment of a fluid supply that provides fluids to a platen according to the present disclosure.

FIG. 8 illustrates a plasma processing system including a platen and a fluid supply according to the present disclosure.

### DETAILED DESCRIPTION

Reference in the specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment.

It should be understood that the individual steps of the methods of the present disclosure may be performed in any order and/or simultaneously as long as the disclosure remains operable. Furthermore, it should be understood that the apparatus and methods of the present disclosure may include any number or all of the described embodiments as long as the disclosure remains operable.

The present teachings will now be described in more detail with reference to exemplary embodiments thereof as shown in the accompanying drawings. While the present teachings are described in conjunction with various embodiments and examples, it is not intended that the present teachings be limited to such embodiments. On the contrary, the present teachings encompass various alternatives, modifications and equivalents, as will be appreciated by those of skill in the art. Those of ordinary skill in the art having access to the teachings herein will recognize additional implementations, modifications, and embodiments, as well as other fields of use, which are within the scope of the present disclosure as described herein. For example, the present teachings may be equally applicable to other types of substrate processing system including the beam-line ion implantation system or other plasma based substrate processing system. In another example, the present disclosure may be equally applicable to various types of substrate including metallic, semiconducting, superconducting, or insulating substrates.

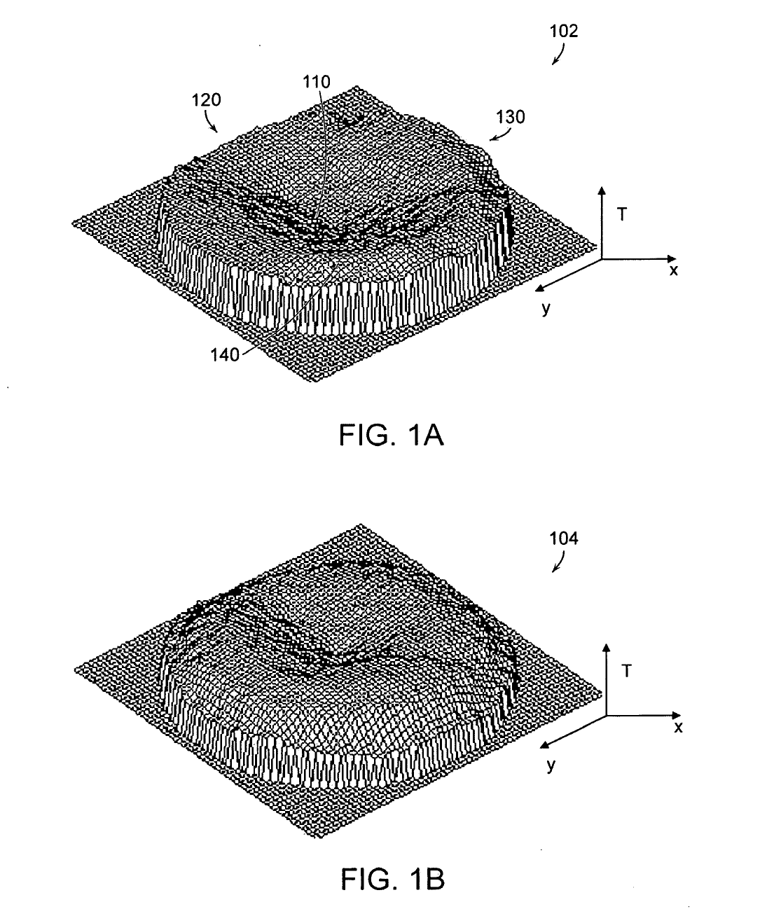

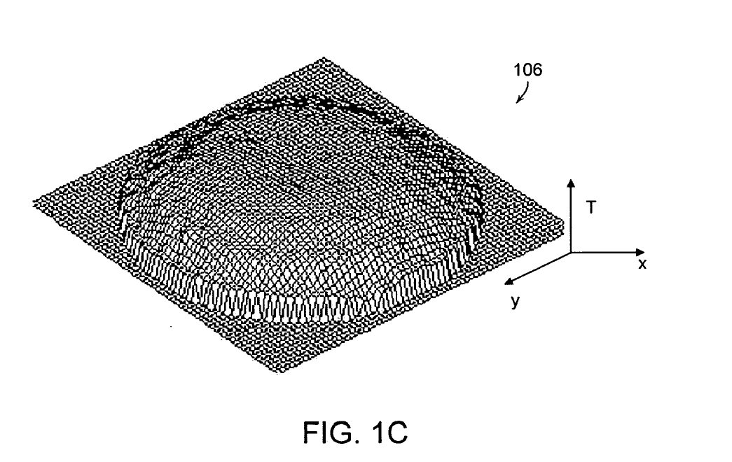

The present disclosure is, at least in part, the recognition that a substrate undergoing plasma processing may have a non-uniform temperature profile in one or both of the radial and the azimuthal directions. FIGS. 1A-1C illustrate three dimensional temperature profiles 102, 104, and 106 of a substrate during plasma processing, such as plasma doping or plasma deposition, under different plasma chamber environments. In the present disclosure, the different environment may be related to different chamber pressures. The T-axis in the temperature profiles 102, 104, and 106 represents the temperature of the substrate.

FIG. 1A illustrates a temperature profile 102 of a substrate during plasma processing, such as plasma doping, under a first plasma processing environment. As illustrated in FIG. 1A, the substrate under the first plasma processing environment may experience temperature variation. For example, the substrate may experience lower temperature near the center 110 of the substrate and a higher temperature near the first periphery region 120. The temperature near the second periphery region 130, meanwhile, may be higher than the temperature near the first periphery region 120. The substrate may experience a relative maximum temperature at a third periphery region 140.

FIG. 1B illustrates a temperature profile 104 of a substrate under a second plasma processing environment. As illustrated in FIG. 1B, the substrate under the second environment may also experience temperature variation along one or both the radial and the azimuthal directions.

FIG. 1C illustrates a temperature profile 106 of a substrate during a third plasma processing condition. Unlike the substrates under the first and second process environment, the substrate under the third environment may have the highest temperature near the center. As illustrated in the figure, the temperature of the substrate under the third environment may vary along one or both the radial and the azimuthal directions. The degree of temperature variation along the azimuthal direction, however, may be less prominent.

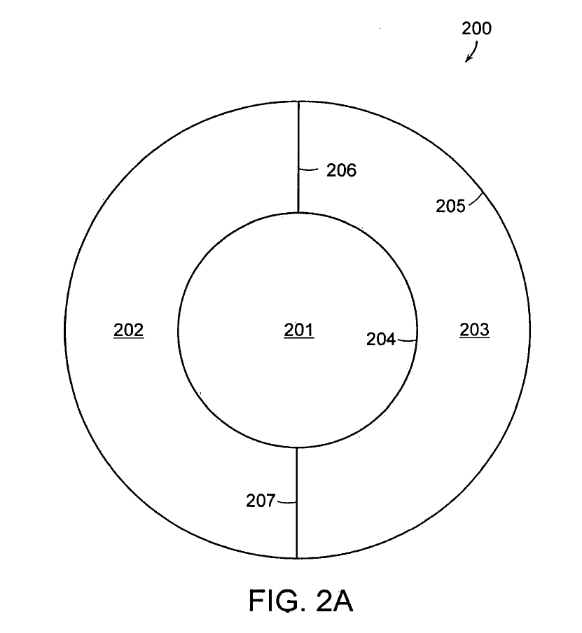

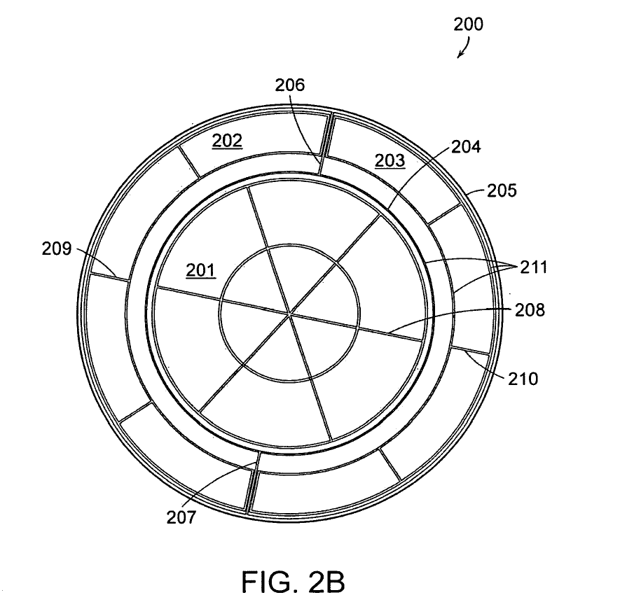

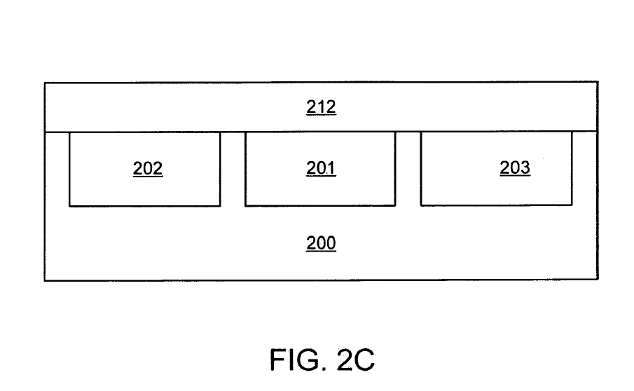

FIG. 2A is a simplified plan view of a platen 200 according to one embodiment of the present disclosure. FIG. 2B is a detailed plan view of the platen 200 shown in FIG. 2A, and FIG. 2C is a side view of the platen 200 supporting a substrate 212. Referring to FIGS. 2A-C, the platen 200 may include first to third regions 201-203; first to third fluid input regions 208-210; and at least one fluid groove 211 for transporting the fluid.

In the present embodiment, the platen 200 may comprises three regions 201-203, four boundaries 204-207, and three fluid grooves 211. However, it is contemplated that the platen 200 may comprise any number of regions, boundaries, and fluid grooves. It is also contemplated that each region 204-207 contains any number of grooves. For example, each region 204-207 may comprise one fluid groove 211 or multiple fluid grooves 211. In another example, at least one region of the platen 200 may not contain a groove 211.

As noted above, the platen 200 may also includes the first to third region fluid input ports 208-310. As illustrated in FIG. 2B, the platen 200 may have a single fluid input port in each region 201-203. In another embodiment, at least one of the regions 201-203 may have a plurality of fluid input ports. In another embodiment, the regions 201-203 may have a different number of fluid input ports. In yet another embodiment, at least one of the regions 201-203 may be without a fluid input port. In the last embodiment, the fluid entering one of the regions 201-203 may be transported to another one of the regions 201-203. The platen 200 may also optionally comprise at least one gas output port (not shown) disposed in at least one of the first to third regions 201-203. Each region 201-203 of the platen 200 may be provided with the fluid output port. However, it is also contemplated that at least one or all of the regions 201-203 may be without the fluid output port. If one of the regions does not contain the fluid output port, the fluid in the region may exit to another, adjacent region or to the plasma chamber.

As shown in FIG. 2C, a substrate 212 may be supported by the platen 200. The back surface of the substrate 212 may face toward the first to third regions 201-203 and the first to fourth boundaries 204-207. In the present disclosure, the fluid may be provided near the back surface, and the fluid may even contact the back surface to provide thermal conduction. Meanwhile, the front surface of the substrate 212 and the surface being processed may be disposed away from the first to third regions 201-203 and the first to fourth boundaries 204-207.

In the present embodiment of the present disclosure, the first region 201 of the platen 200 may be disposed near the center, whereas the second and third regions 202, 203 may be disposed near the first region 201. Although the platen 200 of the present embodiment may include three regions provided in particular locations, those of ordinary skill in the art will recognize that the location of each region is not limited.

Shapes of different regions are also not limited in the present disclosure. For example, the platen 200 of the present embodiment may be configured such that the first region 201 near the center has a substantially circular geometry, whereas, the second and third regions 202 and 203 may have shapes that are mirror image of one another. However, those of ordinary skill in the art will recognize the regions of the platen of the present disclosure may have other shapes or geometries. For example, the platen 200 may be configured such that none of the regions is a mirror image of another region. Those of ordinary skill in the art will also recognize that the shape or geometry of different regions may be the same or different. For example, the regions may have same or different heights such that the regions may have same or different volumes.

In the present disclosure, the platen 200 may be configured in the regions 201-203 to have a portion that is directly adjacent to a portion of another region. For example, the platen 200 may be shaped such that at least a portion of the second region 202 is adjacent to at least a portion of the third region 203. However, those of ordinary skill in the art will recognize the platen may be configured such that there are regions that are not directly adjacent to another region. For example, the platen may comprise three regions disposed side-by-side, where the first region is disposed near the center of the platen and the second and third regions are disposed opposite sides of the first region. In such an example, the second and third regions do not necessarily have portions that are adjacent to one another.

As described herein, first to fourth boundaries 204-207 may define the first to third regions 201-203. The first boundary 204 of the platen 200 may be positioned between the first and second regions 201 and 202 and/or the first and third regions 201 and 203. The second boundary 205 may be proximate to the periphery of the platen 200, and the third and fourth boundaries 206 and 207 may be disposed between the second region 202 and the third region 203. In one embodiment, the first boundary 204 may have a diameter of, for example, about 100 mm, and a thickness of, for example, about 1 mm. Meanwhile, the second boundary 205 may have a diameter of, for example, about 295 mm and a thickness of, for example, about 2 mm. Furthermore, the fluid groove 211 may have a thickness of about 1 mm and a depth of about 0.5 mm.

In the present embodiment, one or more types of fluid may be provided to one or more regions 201-203. In the regions 201-203, the fluid may be provided near or may even contact the back surface of the substrate 212 to provide the thermal conduction. Although the present embodiment discloses fluid being provided to each of the regions, it is also contemplated that there may be at least one region where fluid is not provided.

In the present disclosure, the fluid may be provided in a static mode, dynamic mode, or a combination thereof. In the static mode, the fluid may be provided and maintained in the regions for a period of time. In the dynamic mode, the fluid may continuously flow into the regions 201-203 to provide the thermal conduction to the platen 212, and then exit the regions 201-203.

In the present disclosure, same or different type of the fluid may be provided to different regions. For example, one or a combination of air, deionized water, Ar, He, H₂, N₂, Xe, and Ne fluid, in gaseous or liquid form, may be provided to the first to third regions 201-203 of the platen 200. In another example, one of the regions 201-203 may be provided with one or a combination of air, water, Ar, He, H2, N2, Xe, and Ne fluid, and another one of the regions 201-203 may be provided with another combination of air, water, Ar, He, H2, N2, Xe, and Ne fluid.

Even if the same type of fluid is provided to different regions, the fluid provided to different regions 201-203 may have same or different properties. For example, the fluid provided to different regions may have the same or different temperatures. In another example, the fluid may be provided to different regions 201-203 at the same or different flow rates. Furthermore, the fluid in different regions may be maintained under at same or different pressure levels.

In the present disclosure, the boundaries 204-207 may act to isolate one region from other regions. In addition, the second boundary 205 may act to isolate the regions 201-203 of the platen 200 from the condition of the plasma chamber. If preferable, at least one channel (not shown), however, may be disposed at one or more boundaries to enable the fluid provided to one region to flow into another region. In the present disclosure, such a channel may be disposed near the top, middle, and/or bottom portion of one or more boundaries 204-207.

If the regions 201-203 are isolated from one another, the condition of the regions may be maintained at the same or different conditions to provide the same or different thermal conductions to different portions of the substrate 212. For example, the regions 201-203 may be maintained at the same or different temperatures to provide the same or different thermal conductions to different portions of the substrate 212. In another example, the regions 201-203 may be maintained at the same or different pressure levels to provide the same or different thermal conduction rates. In another example, the fluid may be provided to different regions at the same or different flow rates. Yet in another example, the regions 201-203 may be provided with the same type of fluid. Alternatively, the regions 201-203 may be provided with different types of fluid with different thermal conductivities in order to provide different thermal conduction. By providing the same or different thermal conductions rate, the platen of the present disclosure may promote or hinder temperature variations, such as those shown in FIG. 1A-1C, in the substrate.

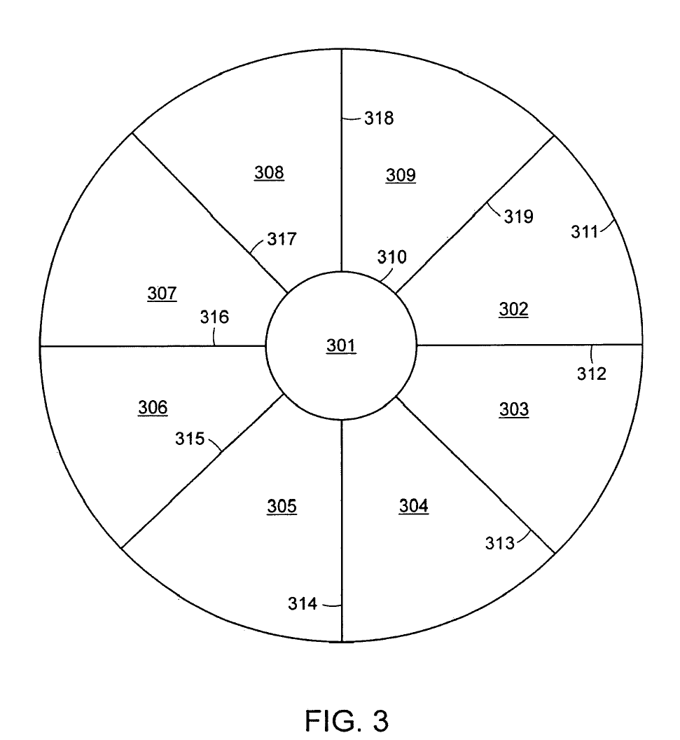

FIG. 3 is a plan view of a platen 300 according to another embodiment of the present disclosure. As illustrated in FIG. 3, the platen 300 comprises a first region 301 near the center of the platen 300, and second to ninth regions 302-309 adjacent to the first region 301. In addition, the platen 300 may comprises a plurality of boundaries 310-319 defining the first to ninth regions 309. As shown in FIG. 3, the first boundary 310 is disposed between the first region 301 and the second to ninth regions 302-309, and the second boundary 311 is disposed proximate to the outer periphery of the platen 300. Meanwhile, each of the third to tenth boundaries 312-319 may be disposed to define the second to ninth regions 302-309.

In the present disclosure, the platen 300 of the present embodiment may have many features similar to those of the platen 200 described with FIGS. 2A-2C. Such similar features may include the fact that the platen 300 may also comprise regions 301-309 that are similarly or differently shaped (see 302-309). In addition, the regions 301-309 of the platen 300 may contain fluid to provided thermal conduction to the substrate (now shown) supported by the platen 300.

Similar to the platen 200 described in connection with FIG. 2, the platen 300 of the present embodiment may be configured such that the conditions of different regions 301-309 may be controlled and maintained under the same or different conditions. As described herein, controlling the conditions of the different regions of the platen 300 may enable the platen 300 to provide a uniform or non-uniform thermal conduction and to minimize non-uniform temperature profile of the substrate. If desirable, the platen 300 may provide uniform or non-uniform thermal conduction to minimize a uniform temperature profile of the substrate as described herein in connection with the platen 200. The conditions of different regions 301-309 of the platen 300 may be controlled by providing the regions 301-309 with fluid having same or different properties. For example, fluid having the same or different thermal conductivities may be provided to the regions 301-309. In another example, the same or different fluid with the same or different temperatures may be provided to regions 301-309.

The conditions of the regions 301-309 may also be controlled by providing fluid under the same or different flow rates. Furthermore, the pressure of different regions may be maintained at the same or different pressure levels. In the present embodiment, the fluid provided to the regions may include, for example, air, water, Ar, He, H₂, N₂, Xe, and Ne, in gaseous or liquid form, or a combination thereof.

Features of the present platen 300 that differs from those of the platen 200 may be the number, shape, dimension, and or relative location of some or all of the regions 301-309.

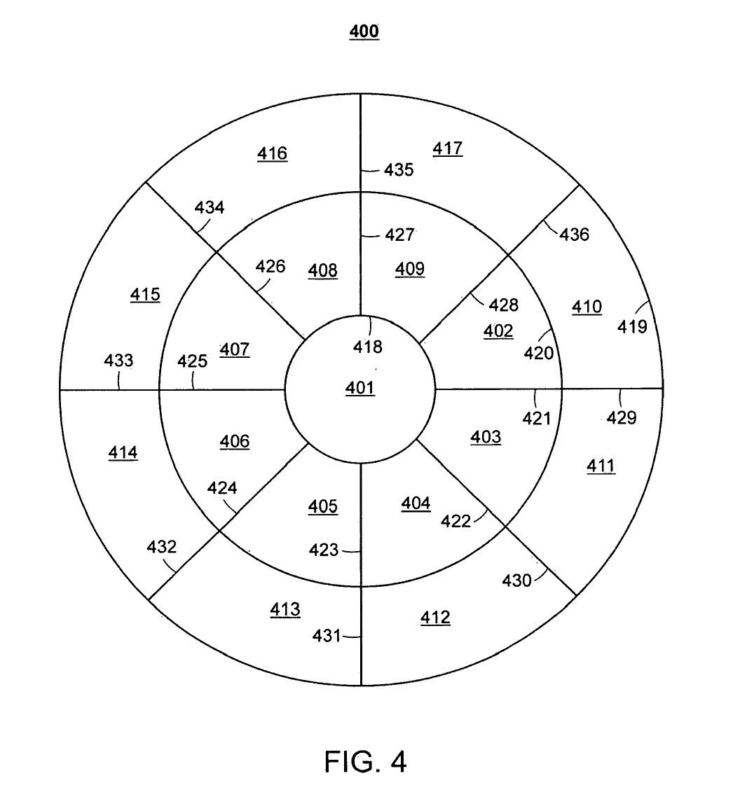

FIG. 4 is a plan view of a platen 400 according to another embodiment of the present disclosure. As illustrated in FIG. 4, the platen 400 may comprise a first region 401 near the center of the platen 400; second to ninth sub-regions 402-409 adjacent to the first region 401; and a tenth to seventeenth sub-regions 410-417 adjacent to the second to ninth sub-regions 402-409. The platen 400 may also comprise a first boundary 418 positioned between the first region 401 and the second to ninth sub-regions 402-409; a second boundary 419 proximate to the periphery of the platen 400; a third boundary 420 positioned between the second to ninth sub-regions 402-409 and tenth to seventeenth sub-regions 410-417. The platen 400 may also include a plurality of sub-boundaries 421-436 defining the second to seventeenth sub-regions 402-417 of the platen 600.

In the present disclosure, the platen 400 of the present embodiment may have several features that are similar to those of the platens 200 and 300. For the purpose of clarity and simplicity, similar features will not be described in connection with FIG. 4.

One different feature of the present embodiment shown in FIG. 4 may be found in the tenth to seventeenth regions 410-417 of the platen 400. As illustrated in FIG. 4, the tenth to seventeenth regions 410-417 may be spaced apart and not directly adjacent to the first region 401. Such a configuration may enable the first region to be, for example, thermally isolated from the tenth to seventeenth regions 410-417.

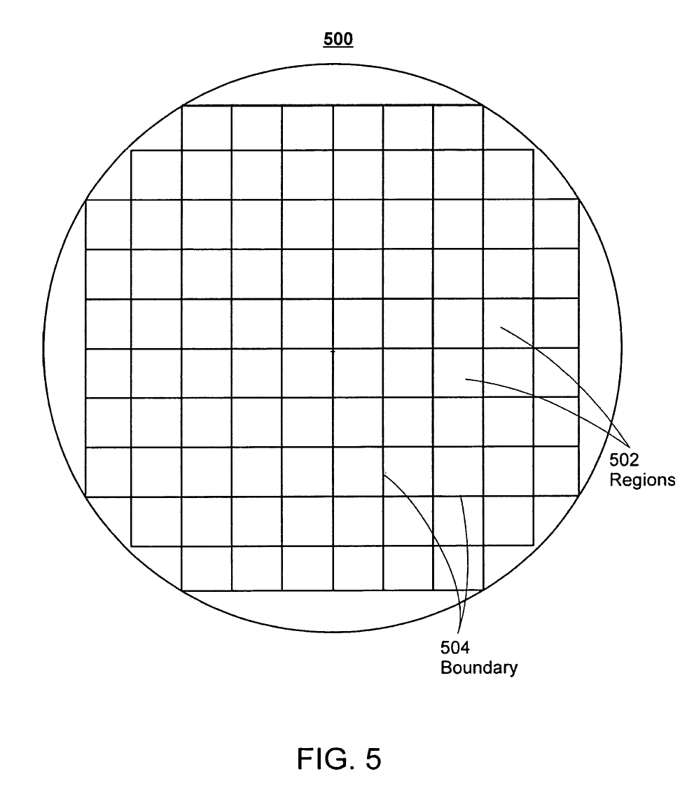

FIG. 5 is a plan view of a platen 500 according to another embodiment of the present disclosure. As illustrated in FIG. 5, the platen 500 of the present embodiment may include a plurality of rectangular regions 502 positioned in an array; a plurality of boundaries 504 positioned to define the regions 502. In the present disclosure, the platen 500 of the present embodiment may include features that are similar to those of the platen 200, 300, and 400 described earlier. For purposes of clarity and simplicity, similar features of the platen 500 will not be described in connection with FIG. 5.

One different feature of the present embodiment shown in FIG. 5 may be found in the shape and dimensions of the regions 502. In addition, the position of each region with respect to other regions 502 may differ. For example, the regions 502 of the platen 500 are not concentric.

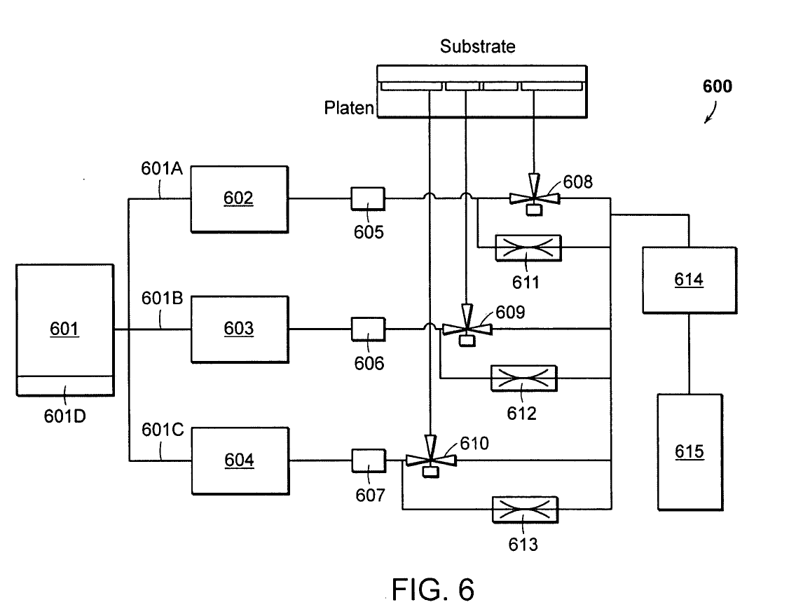

FIG. 6 illustrates a fluid supply unit 600 for supplying fluid to the platen 200, 300, 400, and 500 according to one embodiment of the present disclosure. The fluid supply unit 600 may comprises a fluid reservoir 601 and a first to third pressure controllers 602-604; and first to third filters 605-607; first to third valves 608-610; first to third orifices 611-613; a ballast tank 614; and a vacuum pump 615.

In the present embodiment, the first to third pressure controller 602-604 may independently control the flow rate and/or pressure of the fluid from the reservoir 601 to the first to third fluid conduits 601A, 601B, and 601C. In addition, the first to third pressure controllers 602-604 may monitor and/or set the pressure of fluids provided to each region. Meanwhile, the first to third filters 605-607 may filter the fluid traveling through the first to third fluid conduits 801A, 801B, and 801C.

The first to third valves 608-610 may control the flow of fluid from the filters 605-607 to the regions of the platen 620 that are in communication with the valves 608-610. The first to third orifices 611-613 connected in parallel to the first to third valves 608-610 may restrict the flow of fluid to the regions of the platen 620.

As illustrated in FIG. 6, the ballast tank 614 may be coupled to the first to third valve 608-610 and to the first to third orifices 611-613. The vacuum pump 615, meanwhile, may be coupled to the ballast tank 614 and generate a pressure differential to transport the fluid from the fluid reservoir 601 via the first to third fluid conduits 601A, 601B, and 601C. In addition, the vacuum pump 615 may generate a pressure differential to evacuate the fluid from the regions of the platen 620. In one embodiment, the fluid supply unit 600 may include at least one temperature controller 601D, such as a heater and/or a cooler that is positioned proximate to the reservoir 601. In another embodiment, one or more temperature controllers (not shown) may be provided to at least one of the first to third fluid conduits 601A, 601B, and 601C in order to independently control the temperature of the fluid in the conduits 601A, 601B, and 601C.

As shown in FIG. 6, the first to third pressure controllers 602-604 may be coupled directly to the reservoir 601. The first pressure controller 602, the first filter 605, and the first valve 608 may be coupled together in series via the first conduit 601A. The second pressure controller 603, the second filter 606, and the second valve 609 may be coupled together in series via the second conduit 601B. The third pressure controller 604, the third filter 607, and third valve 610 may be coupled together in series via the third conduit 601C. Meanwhile, the first to third orifices 611-613 may be coupled in parallel with respective ones of the first to third valves 608-610. The ballast tank 614 may be coupled to the first to third valves 608-610 and to the first to third orifices 611-613. The vacuum pump 615 may be coupled to the ballast tank 614.

In operation, the vacuum pump 615 may generate a pressure differential and transport the fluid in the reservoir 601 to the first to third fluid conduits 601A-601C. As noted above, the fluid contained in the fluid reservoir 601 and transported via the first to third fluid conduits 601A-601C may be one of or a combination of air, de-ionized water air, Ar, He, H₂, N₂, Xe, and Ne. The fluid contained in the fluid reservoir 601 can be in liquid or in gaseous form.

The pressure of the fluid flowing via the first to third fluid conduit 601A, 601B, and 601C may be independently controlled by the pressure controllers 602-604. For example, the pressure controllers 602-604 may be used to monitor and to set the flow rate of the fluid flowing through any one of the first to third fluid conduit 601A, 601B, and 601C to high flow rate, intermediate flow rate, or to low flow rate. Alternatively, the pressure controllers 602-604 may prevent the fluid from flowing through any one of the first to third fluid conduit 601A, 601B, and 601C. Each of the filters 605-607 may filter the fluid, and the valves 608-610 may control the flow of the fluid to the regions of the platen 300, the orifices 611-613, and the ballast tank 614. The combination of the pressure controller 602-604, the ballast tank 614, the orifice 611-613, and the vacuum pump 615 may maintain the fluid pressure in the regions in the platen 300 at one or more desired levels.

For example, each pressure controller 602-604 may be configured to provide fluid at predetermined pressures. The ballast tank 614 and vacuum pump 615 are configured to rapidly pump and provide the pressure differential to the fluid in the first to third fluid conduit 601A, 601B, and 601C. The first to third orifices 611-613 may reduce the flow of fluid from the pressure controller 602-604 to the ballast tank 614. The first to third orifices 611-613 are also designed to maintain the pressure in each of region of the platen 300 at one or more predetermined levels.

In the present disclosure, the fluid supply unit 600 may also comprise fluid output conduits (not shown) that enable the fluid contained in the regions to exit the regions and provided to the ballast tank 614. Such fluid output conduits may also be coupled to the first to third valves 608-610.

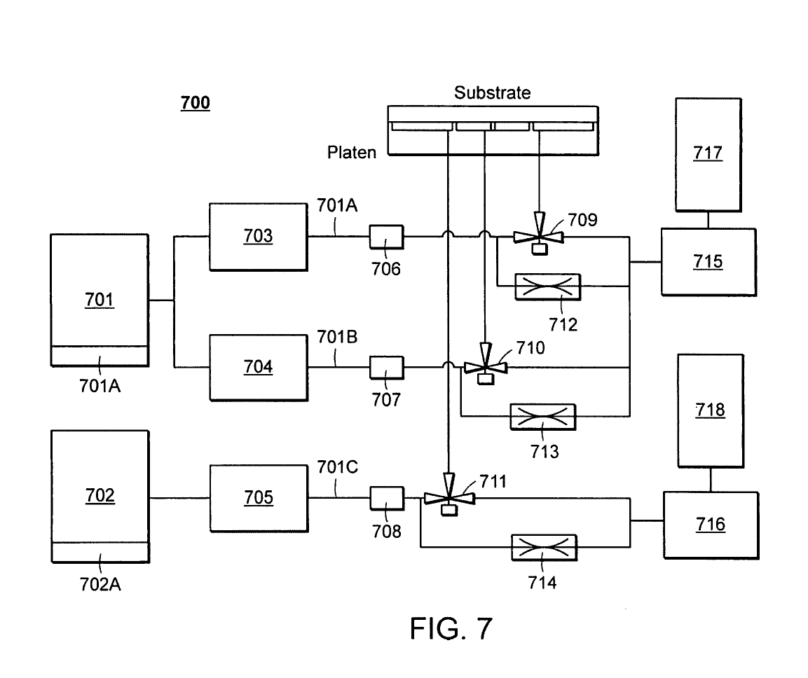

FIG. 7 illustrates another embodiment of a fluid supply unit 700 according to the present disclosure. The fluid supply unit 700 may include features similar to the features of the fluid supply unit 600. The fluid supply unit 700, however, may include a plurality of fluid reservoirs 701 and 702; a plurality of corresponding ballast tanks 715 and 716, and a plurality of vacuum pumps 717 and 718.

As illustrated in FIG. 7, the fluid supply unit 700 may include first and second fluid reservoirs 701 and 702. However, those of ordinary skill in the art will recognize that the fluid supply unit 700 may include a different number of fluid reservoir. In the present disclosure, the reservoirs 701 and 702 may contain the same or different types of fluid. For example, the reservoirs 701 and 702 may contain different fluid having different thermal conductivity. In addition, the reservoir 701 and 702 may contain fluid having the same or different property (e.g. temperature and flow rate). Each of the first and second fluid reservoirs 701 and 702 may include temperature controllers 701A and 702A to control the fluid temperature. As the temperature controller of other embodiments described herein, the temperature controllers 701D and 702D of the present embodiment may be heaters and/or coolers. Furthermore, at least one temperature controller (not shown) may be provided near the conduits 701A, 701B, and 701C in addition or in alternative to the temperature controllers 701D and 702D near the reservoirs 701 and 702.

As illustrated in FIG. 7, the first and second pressure controllers 703-704 may be coupled to the first reservoir 701, whereas a third pressure controller 705 may be coupled to the second reservoir 702. The first pressure controller 703 may be coupled in series with the first filter 706 and the first valve 709 via the first fluid conduit 701A. Also, the second pressure controller 704 may be coupled in series with the second filter 707 and the second valve 710 via the second fluid conduit 701B. In addition, the third pressure controller 705 may be coupled in series with the third filter 708 and the third valve 711 via the third fluid conduit 701C.

As illustrated in FIG. 7, each of the first to third orifices 712-714 may be connected in parallel to the first to third valves 709-711, respectively. The first ballast tank 715 may be coupled to the first and second valve 709, 710 and to the first and second orifices 712 and 713. Also, the second ballast tank 716 may be coupled to the third valve 711 and to the third orifice 714. Furthermore, the first and second vacuum pumps 717 and 718 may be coupled to the first and second ballast tanks 715 and 716, respectively.

The operation of the fluid supply unit 700 may be similar to the operation of the fluid supply unit 600 described in connection with FIG. 6. As described herein, the supply unit 700 may be able to provide different types of fluid with different fluid characteristics and operating conditions.

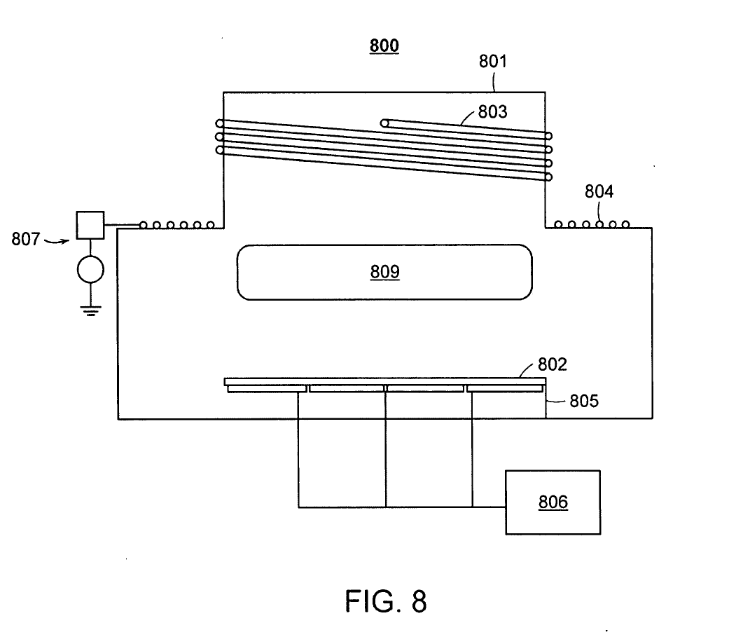

FIG. 8 illustrates a plasma processing system 800 including a platen 805 and a fluid supply 806 according to the present disclosure. In one embodiment, the plasma processing system 800 is a plasma doping system. However, one skilled in the art will appreciate that the platen and fluid supply units of the present disclosure may be applied to any type of plasma based processing system and any other types of processing systems using a platen. For example, the plasma processing system may be another type of doping system, such as a beam-line ion implantation system or a plasma based etching or deposition system.

The plasma processing system 800 includes at least one chamber 801 where a substrate 802 is disposed and processed. The chamber 801 may include a heater and/or a cooler that controls the temperature of the platen 805 and/or the substrate 802. A fluid supply unit 806, such as the fluid supply units 600 and 700 described in connection with FIGS. 6 and 7 that were described earlier with FIGS. 6 and 7, may provide at least one type of fluid to each region of the platen 805. In one embodiment, the fluid supply unit 806 includes pressure controllers, such as the pressure controllers 602-604 and 703-705 that are described above. The pressure controllers may be configured to monitor and/or to set the pressure of fluids transported to each region of the platen 805. Alternatively, the system 800 may include one or more fluid monitors, other than the pressure controllers, that monitor the fluid properties in each region of the platen 805. The plasma processing system 800 may also include a temperature monitor that monitors the temperature variation of the substrate 802.

The chamber 801 includes a first 803 and a second coil 804. At least one of the first and the second coil 803, 804 is an active coil that is directly connected to an RF power source 807. In some embodiments, one of the first and the second coils 803, 804 is a parasitic coil or parasitic antenna. The term “parasitic antenna” is defined herein to mean an antenna that is in electromagnetic communication with an active antenna, but that is not directly connected to a power supply. In other words, a parasitic antenna is not directly excited by a power supply, but rather is excited by an active antenna positioned in electromagnetic communication with the parasitic antenna. In some embodiments of the present disclosure, one end of the parasitic antenna is electrically connected to ground potential in order to provide antenna tuning capabilities. In this embodiment, the parasitic antenna includes a coil adjuster that is used to change the effective number of turns in the parasitic antenna coil. Numerous different types of coil adjusters, such as a metal short, may be used.

In operation, the substrate 802 may be placed in the chamber 801, and the chamber 801 may be evacuated. The fluid supply unit 806 may provide at least one type of fluid at a predetermined pressure and/or temperature to different regions of the platen 805. The fluid with the predetermined pressure and/or temperature provided to the different regions of the platen 805 may achieve a desired thermal conductivity profile in the substrate 802.

In one embodiment, the fluid supply unit 806 also monitors the pressure of fluid in at least one of the regions of the platen 805. If the fluid supply unit 806 detects the presence of a fluid leak, the pressure controllers 602-604, 703-705 may signal the system 800 to terminate the process or to take a corrective measure to maintain the desired substrate 802 temperature profile. Fluid leakage between regions may be determined by detecting a decrease in the pressure in one region and/or an increase in the pressure in another region. Fluid leakage between regions in the platen 805 may also be determined by detecting an increase in temperature variation of the substrate 802. The overall process yield may be improved by detecting fluid leakage and taking corrective measures.

Radio frequency power is applied to at least one of the first and second coils 803 and 804. The at least one powered coil generates a plasma 809. Ions from the plasma 809 are then directed toward the substrate 802 by, for example, applying a bias to the platen 805 or the substrate 802, either directly or indirectly.

By providing fluids to different regions of the platen 805 with different pressures and/or temperatures, different heat conduction rates (i.e. cooling and/or heating rates) may be provided to different regions of the substrate 802. Therefore, the fluid supply unit 806 may provide the desired thermal conductivity profile for a particular plasma process. There are an almost unlimited number of possible thermal conductivity profiles that may be used to perform numerous different processes. In the simplest example, the fluid supply unit 806 may be used to provide a relatively uniform thermal conductivity profile in the platen 805 that minimizes temperature variations across the platen 805.

In one embodiment, at least two different types of fluids are provided to at least two different regions of the platen 805. In various embodiments, the thermal conductivities of the different types of fluids may be significantly different or may be similar. Using at least two different types of fluids may provide a relatively uniform thermal conductivity profile without using different fluid pressures in different sections of the platen 805. For example, the fluid supply unit 806 may provide a relatively uniform thermal conductivity profile by providing a fluid with a relatively low thermal conductivity, such as N₂, to one region of the platen 805 near the portion of the substrate 802 with a relatively low temperature. In addition, the fluid supply unit 806 may provide fluid with a relatively high thermal conductivity, such as He, to another region near the substrate 802 with a relatively high temperature.

One advantage of the platen of the present disclosure may be that the platen may be capable of providing or maintaining different types of fluid and/or fluid having same or different properties. As such, the platen of the present disclosure may be capable of reducing volume requirement of fluid that may be effective, but costly. For example, He, although very effective in providing thermal conduction, is expensive. The overall cost of the plasma processing may be reduced by providing He to only portions of the substrate that require high heat conduction, and by providing less costly fluid with lower thermal conduction to portions that require less heat conduction.

### Equivalents

While the present teachings are described in conjunction with various embodiments and examples, it is not intended that the present teachings be limited to such embodiments. On the contrary, the present teachings encompass various alternatives, modifications and equivalents, as will be appreciated by those of skill in the art, which may be made therein without departing from the spirit and scope of the disclosure.

What is claimed is:

1. A platen for a processing system, the platen comprising:
a. a first and a second thermal region that are separated by at least one boundary;
b. a first fluid conduit that is positioned in the first thermal region;
c. a second fluid conduit that is positioned in the second thermal region; and
d. a fluid reservoir having a first output that is coupled to the first fluid conduit and a second output that is coupled to the second fluid conduit, the fluid reservoir providing fluid to the first fluid conduit with first fluid condition that provides a first thermal conductivity to the first thermal region and providing fluid to the second fluid conduit with second fluid condition that provides a second thermal conductivity to the second thermal region so that a predetermined thermal conductivity profile is achieved in the platen.

2. The platen of claim 1 wherein the first and second thermal regions comprise a separate fluid input port.

3. The platen of claim 1 wherein at least one of the first and the second fluid conduit comprises a groove in the platen for transporting fluid.

4. The platen of claim 1 wherein the first and second fluid conditions comprises at least one of fluid flow rate, fluid pressure, fluid temperature, fluid thermal conductivity, and fluid type.

5. The platen of claim 1 wherein the predetermined thermal conductivity profile comprises a relatively uniform temperature profile across the platen.

6. The platen of claim 1 wherein the predetermined thermal conductivity profile comprises a thermal conductivity profile that compensates for thermal non-uniformities in both a radial and an azimuthal direction of the platen.

7. The platen of claim 1 wherein the predetermined thermal conductivity profile comprises a thermal conductivity profile that compensates for thermal non-uniformities generated in a plasma process which result in a central region of the platen having a relatively low temperature compared with a peripheral region of the platen.

8. The platen of claim 1 wherein the fluid comprises at least of a liquid and a gas.

9. The platen of claim 1 wherein the fluid comprises a combination of at least one liquid and at least one gas.

10. A platen for a processing system, the platen comprising:
a. a plurality of thermal regions, each of the plurality of thermal regions being separated by at least one boundary and comprising at least one fluid conduit; and
b. a plurality of fluid reservoirs, an output of each of the plurality of fluid reservoirs being coupled to an input of at least one of the plurality of thermal regions, the plurality of fluid reservoirs providing fluid to the plurality of thermal regions with different fluid conditions so that a predetermined thermal conductivity profile is achieved in the platen.

11. The platen of claim 10 wherein at least two of the plurality of fluid reservoirs provide fluids with different thermal conductivities to at least two of the plurality of thermal regions.

12. The platen of claim 10 wherein at least one of the plurality of fluid reservoirs provides fluid to at least two of the plurality thermal regions.

13. The platen of claim 10 wherein at least two of the plurality of thermal regions comprises a separate fluid input port that is coupled directly to one of the plurality of fluid reservoirs.

14. The platen of claim 10 wherein the fluid conditions comprise at least one of fluid flow rate, fluid pressure, fluid temperature, fluid thermal conductivity, and fluid type.

15. The platen of claim 10 wherein the predetermined thermal conductivity profile comprises a relatively uniform temperature profile across the platen.

16. The platen of claim 10 wherein the predetermined thermal conductivity profile comprises a thermal conductivity profile that compensates for thermal non-uniformities in both a radial and an azimuthal direction of the platen.

17. The platen of claim 10 wherein the predetermined thermal conductivity profile comprises a thermal conductivity profile that compensates for thermal non-uniformities generated in a plasma process which result in a central region of the platen having a relatively low temperature compared with a peripheral region of the platen.

18. A method of achieving a predetermined thermal conductivity profile in a platen for a processing system, the method comprising:
a. providing a platen having a plurality of thermal regions separated by at least one boundary;
b. flowing fluid from at least one fluid reservoir into fluid conduits in the plurality of regions; and
c. selecting fluid conditions of fluid flowing in fluid conduits in at least two of the plurality of regions so that a predetermined thermal conductivity profile is achieved in the platen.

19. The method of claim 18 wherein the process comprises a plasma process.

20. The method of claim 18 wherein the fluid comprises a combination of at least one liquid and at least one gas.

21. The method of claim 18 wherein the selecting fluid conditions comprises selecting at least one of fluid flow rate, fluid pressure, fluid temperature, fluid thermal conductivity, and fluid type.

22. The method of claim 18 wherein the predetermined thermal conductivity profile comprises a relatively uniform temperature profile across the platen.

23. The method of claim 18 wherein the predetermined thermal conductivity profile comprises a thermal conductivity profile that compensates for thermal non-uniformities in both a radial and an azimuthal direction of the platen.

24. The method of claim 18 wherein the predetermined thermal conductivity profile comprises a thermal conductivity profile that compensates for thermal non-uniformities generated in a plasma process which result in a central region of the platen having a relatively low temperature compared with a peripheral region of the platen.

25. A platen for a processing system, the platen comprising:
a. a platen having a plurality of thermal regions separated by at least one boundary;
b. a means for flowing fluid from at least one fluid reservoir into fluid conduits in the plurality of regions; and
c. a means for selecting fluid conditions of fluids flowing in at least two fluid conduits in at least two of the plurality of regions so that a predetermined thermal conductivity profile is achieved in the platen.
